(19) United States
(12) Patent Application Publication
(10) Pub. No.: US 2012/0085285 A1
(43) Pub. Date: Apr. 12, 2012

(54) SEMICONDUCTOR GROWTH APPARATUS

(75) Inventor: Shoji Hiramatsu, Fukuoka-ken (JP)

(73) Assignee: KABUSHIKI KAISHA TOSHIBA, Tokyo (JP)

(21) Appl. No.: 13/048,042

(22) Filed: Mar. 15, 2011

(30) Foreign Application Priority Data
Oct. 6, 2010 (JP) 2010-226298

(51) Int. Cl. C23C 16/00

(52) U.S. Cl. 118/725

(57) ABSTRACT

A according to one embodiment, a semiconductor growth apparatus growing a semiconductor layer on a substrate includes a susceptor, a heater element, a gas feed unit and an auxiliary susceptor. The susceptor includes a first major surface, a second major surface and a substrate holder provided in the first major surface. The heater element heats the susceptor from the second major surface side. The gas feed unit feeds source gases of the semiconductor layer flowing along the first major surface. The auxiliary susceptor is disposed on a portion adjacent to the substrate holder on an upstream side in the source gas flow in the first major surface.

### CROSS-REFERENCE TO RELATED APPLICATIONS

This application is based upon and claims the benefit of priority from Japanese Patent Application No. 2010-226298, filed on Oct. 6, 2010; the entire contents of which are incorporated herein by reference.

### FIELD

Embodiments described herein relate generally to a semiconductor growth apparatus.

### BACKGROUND

An epitaxial growth of a semiconductor layer is an essential technology among manufacturing processes of semiconductor devices. There have been various technical developments proceeded in this field. Especially, a crucial technique for manufacturing light emitting devices and high speed electron devices is the hetero-epitaxy by which the semiconductor layers having a different composition are grown on a substrate.

For example, the compound semiconductor expressed by the formula AlₓIn_{y}Ga_{1-(x+y)}N (0<x, y<1, 0<x+y<1) can be grown on GaAs wafer, and it is possible to make the light emitting diode (LED) that emits red, yellow or green light using the hetero-structure which includes AlInGaP layers being different from each other in the composition x and y. On the other hand, it is important for the LED to reduce manufacturing cost. In this regard, controllability of the composition in the AlInGaN crystal and homogeneity of the composition within the wafer face are desired to be improved.

However, it is not always the case in a previous semiconductor growth apparatus that the controllability and the homogeneity of the semiconductor composition are sufficient for the manufacturing, and there are some rooms to be improved. Therefore, the semiconductor growth apparatus is required to be improved in the controllability and the homogeneity of the semiconductor composition, whereby the manufacturing yield can be raised.

### BRIEF DESCRIPTION OF THE DRAWINGS

FIG. 1 is a schematic cross-sectional view illustrating the structure of a semiconductor growth apparatus according to an embodiment;

FIG. 2 is a schematic plan view showing a susceptor of the semiconductor growth apparatus according to the embodiment;

FIG. 3 is a cross-sectional view schematically showing the structure of the susceptor according to the embodiment;

FIG. 4A and FIG. 4B are schematic views describing the relationship between source gas flows and incorporation of elements constituting a semiconductor layer in the semiconductor growth apparatus;

FIG. 5 is a graph showing a photoluminescence (PL) wavelength distribution in a semiconductor layer grown by using a susceptor according to a comparative example;

FIG. 6 is a graph showing a PL wavelength distribution in a semiconductor layer grown by using the susceptor according to the embodiment;

FIG. 7 is a graph showing a wavelength distribution of lights emitted from LED chips including the semiconductor layer grown by using the susceptor according to the comparative example;

FIG. 8 is a graph showing a wavelength distribution of lights emitted from LED chips including the semiconductor layer grown by using the susceptor according to the embodiment;

FIG. 9 is a schematic view illustrating the cross-section of a susceptor according to a variation of the embodiment; and

FIG. 10A and FIG. 10B are schematic plan views of susceptors according to other variations of the embodiment.

### DETAILED DESCRIPTION

In general, according to one embodiment, a semiconductor growth apparatus growing a semiconductor layer on a substrate includes a susceptor, a heater element, a gas feed unit and an auxiliary susceptor. The susceptor includes a first major surface, a second major surface and a substrate holder provided in the first major surface. The heater element heats the susceptor from the second major surface side. The gas feed unit feeds source gases of the semiconductor layer flowing along the first major surface. The auxiliary susceptor is disposed on a portion adjacent to the substrate holder on an upstream side in the source gas flow in the first major surface.

Various embodiments will be described hereinafter with reference to the accompanying drawings. In the following embodiments, like components in the drawings are labeled with like reference numerals, with the detailed description thereof omitted as appropriate, and the different components are described as appropriate.

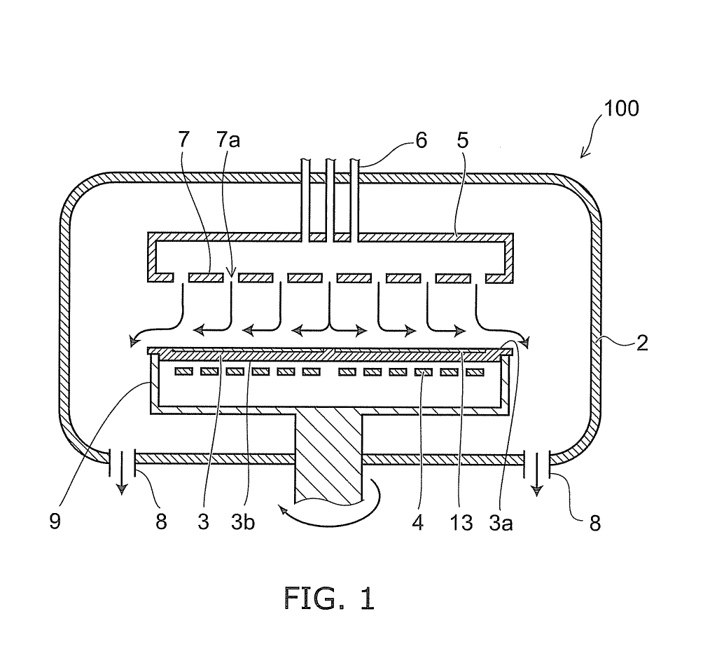

FIG. 1 is a schematic cross-sectional view illustrating the structure of a semiconductor growth apparatus 100 according to the embodiment. The semiconductor growth apparatus 100 is, for example, an MOCVD (Metal Organic Chemical Vapor Deposition) apparatus that enables a semiconductor layer to grow on a surface of a substrate.

As illustrating in FIG. 1, the semiconductor growth apparatus 100 includes, for example, a susceptor 3 which holds a substrate 13 and a gas feed unit 5 in a reactor chamber 2 made of stainless steel. The gas feed unit 5 feeds source gases to a first major surface 3a for growing the semiconductor layer.

For example, TMA (trimethylaluminum), TMG (trimethylgallium), TMI (trimethylindium) and phosphine (PH₃) can be used as the source gases. These source gases are supplied into the gas feed unit 5 via a pipe arrangement 6, and are ejected toward the first major surface 3a from a plurality of openings 7a provided in a plate 7 opposed to the first major surface 3a.

As shown by allows in FIG. 1, the source gases flow along the first major surface 3a from a center to an edge, and flow out via exhausts 8 provided around the susceptor 3 to a gas scrubber (not illustrated).

The susceptor 3 is supported by a susceptor holder 9. The susceptor holder 9 includes a heater element 4 disposed therein. The heater element 4 heats the susceptor 3 from a second major surface 3b side, maintaining the susceptor 3 at a predetermined temperature.

Further, the susceptor holder 9 is rotated (i.e. the susceptor 3 is rotated in a plane including the first major surface 3a), whereby the source gas concentration becomes uniform above a surface of the substrate 13. Thereby, a homogeneous semiconductor layer can be grown on the substrate 13.

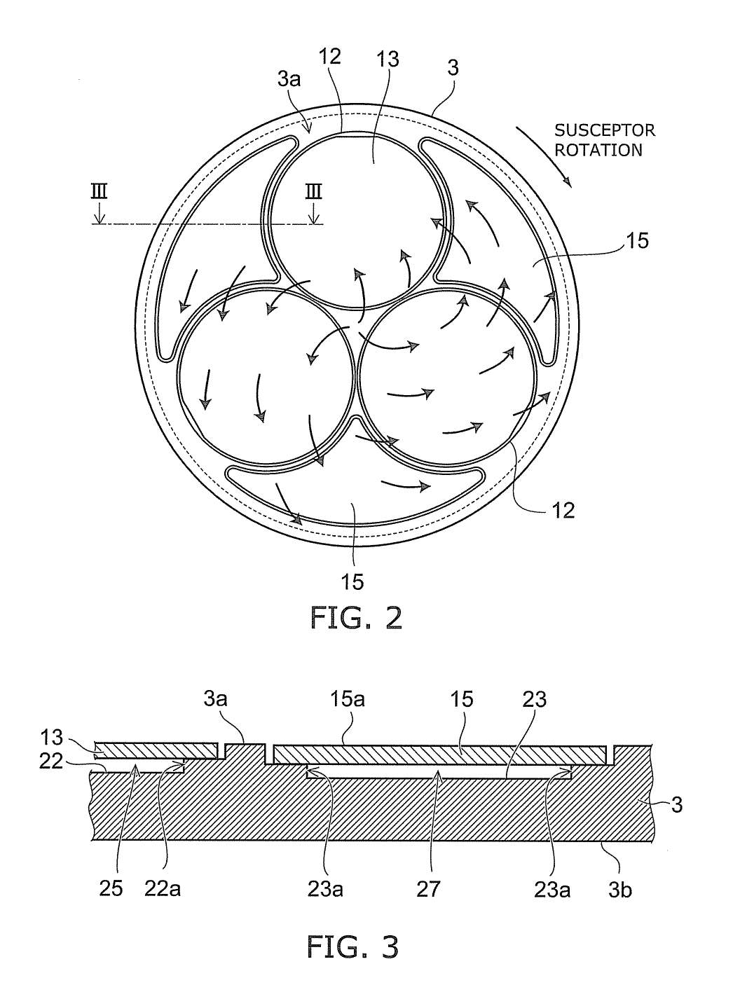

FIG. 2 is a plan view schematically illustrating the susceptor 3 of the semiconductor growth apparatus 100. The susceptor 3 can be made of, for example, a circular silicon plate and includes substrate holders 12. Alternatively, the susceptor 3 may be made of a carbon plate with SIC coat.

The susceptor 3, illustrating in FIG. 2 as an example, includes three substrate holders 12 that are provided in the first major surface 3a and are able to hold the substrate 13 respectively. For example, the substrate 13 may be a GaAs wafer having a diameter of 3 inches.

The susceptor 3 can be rotated, for example, in a clockwise direction. Thereby, the source gases ejected from the gas feed unit 5 into the first major surface 3a may flow spirally from the center of the susceptor 3 to the outer side as illustrated by arrows in FIG. 2.

According to the embodiment, the susceptor 3 includes three auxiliary susceptors 15 disposed on peripheral portions along an outer circumference, and the auxiliary susceptor 15 covers the surface of the susceptor 3 except for the substrate holder 12.

For example, FIG. 3 is a schematic cross-sectional view illustrating the structure of the susceptor 3 along III-III line in FIG. 2. As illustrated in FIG. 3, susceptor 3 includes a first depression 22 as the substrate holder 12 and a second depression 23 in the peripheral portion where the auxiliary susceptor 15 is disposed.

The depression 22 of the substrate holder 12 holds the substrate 13. As shown in FIG. 3, the depression 22 is formed of two levels and includes a step 22a along a sidewall; and the periphery of the substrate 13 is supported by the step 22a. Thereby, a gap 25 is formed between the bottom face of the depression 22 and the substrate 13 placed on the substrate holder 12. For example, the gap 22 absorbs warp of the substrate 13, whereby the substrate 13 can be stably held in the depression 22.

On the other hand, the depression 23 provided in the peripheral portion holds the auxiliary susceptor 15 therein. The depression 23 is also formed of two levels and includes a step 23a along a sidewall, and the periphery of the susceptor 15 is supported by the step 23a. Thereby, a gap 27 is formed between the bottom face of the depression 23 and the auxiliary susceptor 15.

For example, in the case where the heater 4 illustrated in FIG. 1 heats the second major surface of the susceptor 3, heat conduction is suppressed by the gap 25 between the substrate 13 and the bottom surface of the depression 22 and then the surface temperature of the substrate 13 is kept lower than that of the susceptor 3. The surface temperature of the auxiliary susceptor 15 can be also maintained to be lower than that of the susceptor 3 owing to the gap 27 formed between the depression 23 and the bottom surface.

In other words, it is possible to reduce the area of high temperature surface exposed in the first major surface 3a, by covering the surface of the susceptor 3 with the auxiliary susceptor 15 disposed in the depression 23.

For example, as illustrated in FIG. 2, by covering the most part of the surface of the susceptor 3 with the auxiliary susceptors 15, except for the substrate holders 12, it becomes possible to close the surface temperature around the substrate 13 to the surface temperature of the substrate 13.

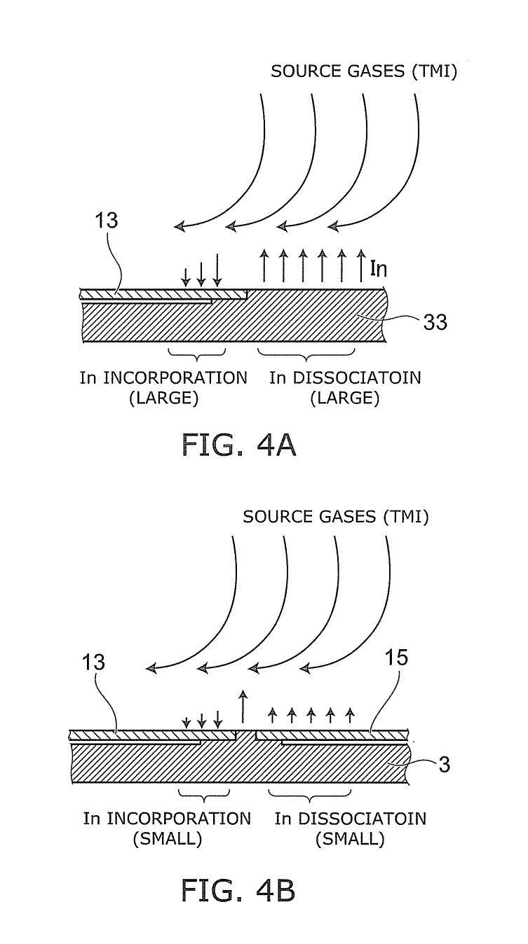

FIG. 4 is a schematic view describing the relationship between the source gas flows and incorporation of the elements constituting the semiconductor layer. FIG. 4A shows a case where a susceptor 33 according to a comparative example is used. The susceptor 33 does not include the auxiliary susceptor 15 disposed. FIG. 4B shows a case where the susceptor 3 according to the embodiment is used.

In the case illustrated in FIG. 4A, the surface temperature of the susceptor 33 is higher than that of the substrate 13. Hence a source gas reaction may proceed easily. For example, in the AlInGaAs crystal growth, indium (In) vapor pressure may increase due to the disassociation of TMI included in the source gases. Additionally, In may also dissociate from reactant deposited on the surface of the susceptor 33.

Thereby, as shown in FIG. 4A, if the temperature surface of the susceptor 33 is high at the upstream side of the source gas flow, In which dissociates above the surface of the susceptor 3 is transported to the surface of the substrate 13 and incorporated into the semiconductor layer. As a result, in the semiconductor layer deposited on the substrate 13, the amount of In contained in the peripheral portion may become larger and may induce unevenness in the composition and thickness.

On the contrary, in the susceptor 3 according to the embodiment, as shown in FIG. 4B, the auxiliary susceptor 15 is disposed on the upstream side of the source gas flow and covers the high temperature surface of the susceptor 3, thereby the surface temperature of the upstream side can be decreased. Hence, the dissociation of the In can be suppressed and the composition can be homogeneous in the semiconductor layer grown on the substrate 13.

Furthermore, the source gases of the semiconductor layer are stably fed on the surface of the substrate 13, and thereby the composition may become more controllable and the thickness may also become more uniform in the semiconductor layer.

To obtain effects mentioned above, the auxiliary susceptor 15 may be disposed to cover at least the surface of the susceptor 3 adjacent to the substrate holder 12 on the upstream side in the source gas flows.

For example, silicon carbide (SIC), boron nitride (BN) or carbon may be used for the auxiliary susceptor 15. Furthermore, by using the same material with the substrate 13 or a material having roughly the same thermometric conductivity therewith, the surface temperature of the auxiliary susceptor 15 may also become closer to the surface temperature of the substrate 13.

The auxiliary susceptor 15 is formed, such that a step height between the surface 15a and the surface of susceptor 3 becomes negligible small. Because the step between the surface 15a of the auxiliary susceptor 15 and the surface of the susceptor 3 induce turbulent flow of the source gases, and unevenness of the composition and the thickness occur in the semiconductor layer.

In this regard, the step height caused by processing accuracy of the auxiliary susceptor 15 and the depression 23 may be allowed as in a range not inducing the turbulent flow of the source gases.

The surface area of the susceptor 3 remaining between the auxiliary susceptor 15 and the substrate holder 12 may be set as small as the processing accuracy allows. Thereby, source gas dissociation can be suppressed on the surface of the susceptor 3, and it may become possible to grow the semiconductor layer having more homogeneous distribution of the composition and the thickness.

For example, in the growth of AlInGaP layer as a light emitting layer of an LED, a lattice mismatch between the AlInGaP layer and the GaAs wafer is controlled to be 0.1% or less. In this case, the surface temperature of the susceptor 33 not including the auxiliary susceptor 15 may become roughly 50 degree higher than that of the GaAs wafer. Thereby, In desorbed from the surface of the susceptor 33 is transferred to a peripheral portion of the GaAs wafer and incorporated in the AlInGaP layer, inducing the shift of the In composition. As a result, a light wavelength may become longer in the peripheral portion and a manufacturing yield may be reduced.

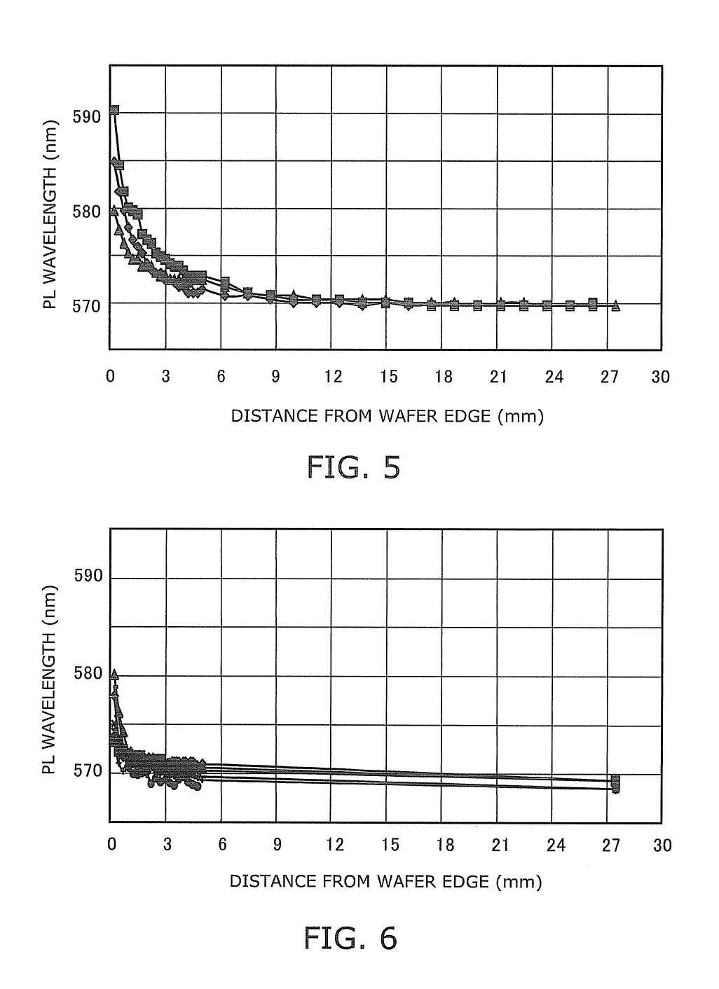

For example, FIG. 5 is a graph showing a photoluminescence (PL) wavelength distribution in the semiconductor layer grown by using the susceptor 33, and FIG. 6 is a graph showing a PL wavelength distribution in the semiconductor layer grown by using the susceptor 3. The horizontal axis indicates a distance between the edge of the substrate 13 and the measuring point therein, and the vertical axis indicates the PL wavelength.

In the peripheral portion where the distance to the edge of the GaAs wafer is small, the PL wavelengths of the semiconductor layer shown in FIG. 5 are distributed as being longer with being closer to the edge of the GaAs wafer (the substrate 13). A PL wavelength of the AlInGaP crystal shifts longer side as an In composition increases. In other words, the PL wavelength distribution shown in FIG. 5 indicates that the In incorporation increases in the peripheral portion of the GaAs wafer.

On the contrary, in the PL wavelength distribution shown in FIG. 6, the longer shift is suppressed in the peripheral portion, indicating that the In incorporation is suppressed. In other words, in the susceptor 3 according to the embodiment, the In dissociation is suppressed by lowering the surface temperature of the portion located on the upstream side of the substrate holder 12 by using the auxiliary susceptor 15.

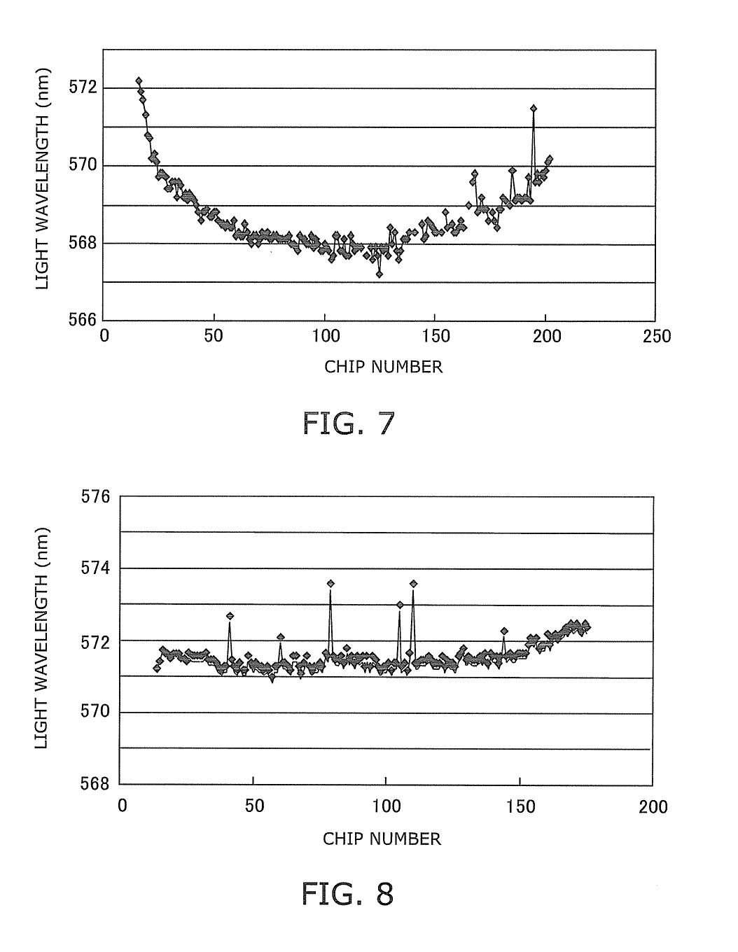

FIG. 7 is a graph showing an emission wavelength distribution of lights emitted from LED chips including the semiconductor (AlInGaP) layer grown by using the susceptor 33 according to the comparative example. The horizontal axis in the graph indicates a sequence number of the LED chips arranged in a line in the GaAs wafer surface, and the vertical axis indicates a wavelength of the LED light.

As shown in FIG. 7, comparing the LED chip located at the center of the GaAs wafer, the LED chip closer to the edge emits a longer emission wavelength light. In the LED chip at the small number side, the wavelength shift becomes larger than 4 nm.

On the contrary, FIG. 8 is a graph showing an emission wavelength distribution of lights emitted from LED chips including the AlInGaP layer grown by using the susceptor 3 according to the embodiment. Likewise in FIG. 7, the horizontal axis indicates a sequence number of the chips and the vertical axis indicates an emission wavelength of the LED chip.

As shown in FIG. 8, the emission wavelength of the LED light is distributed roughly within the wavelength range of 1 nm with respect to the emission wavelength at the center of the sequence number, except for some singularity chips emitting longer wavelength lights. Specifically, it is indicated that the composition distribution becomes more homogeneous in the AlInGaP layer grown by using the susceptor 3, resulting in the improved emission wavelength distribution of the LED.

As mentioned above, by using the susceptor 3 according to the embodiment, it may become possible to improve the homogeneity of the crystal composition allover the AlInGaP layer grown on the GaAs wafer and to raise the manufacturing yield.

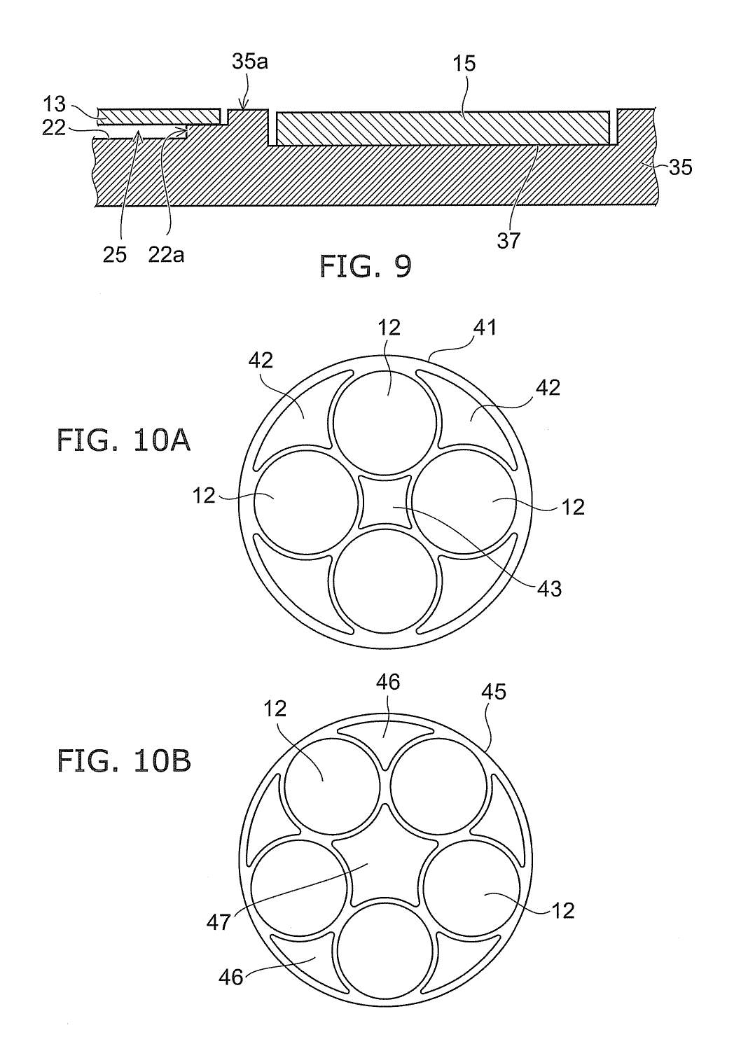

FIG. 9 is a schematic view illustrating the cross-section of a susceptor 35 according to a variation of the embodiment.

In the susceptor 35 according to the variation, the depression 37 housing the auxiliary susceptor 15 does not include the step and the auxiliary susceptor 15 is in directly contact with the bottom face.

By selecting a material of the auxiliary susceptor 15 having smaller thermometric conductivity than that of the material of the susceptor 35, it may become possible to lower the surface temperature of the auxiliary susceptor 15. For example, in the case where a silicon plate is used for the susceptor 35, aluminum nitride (AlN), sapphire or the like may be used for a material of the auxiliary susceptor 15.

FIG. 10A and FIG. 10B are schematic plan views of susceptors 41 and 45 according to other variations of the embodiment. The susceptor 41 illustrated in FIG. 10A includes four substrate holders 12. Likewise the susceptor 3 shown in FIG. 2, auxiliary susceptors 42 are disposed in the peripheral portion. Furthermore, an auxiliary susceptor 43 is additionally disposed in the center portion.

On the other hand, as illustrated in FIG. 10B, the susceptor 45 includes five substrate holders 12. The susceptor 45 also includes auxiliary susceptors 46 disposed in the peripheral portion and an auxiliary susceptor 47 disposed in the center portion.

Thus, as the number of the substrates set on a susceptor increases, the exposed area of the high temperature susceptor surface increases therein. Hence, the composition and the thickness may easily become inhomogeneous in the semiconductor layers grown on the substrates. Therefore, it is advantageous to dispose the auxiliary susceptors according to the embodiment, whereby the exposed area of the high temperature surface decreases in the susceptor.

For instance, the surface of the center portion of the susceptor, which locates on the upstream side for all substrates set in the susceptor, increases as the number of the substrate holders increases, resulting in the wider exposed area of high temperature. Therefore, the auxiliary susceptors 43 and 47 disposed in the center portions may contribute to the homogeneity of the composition and thickness in the semiconductor layers grown on all substrates set on the susceptors 41 and 45 respectively.

The semiconductor growth apparatus 100 according to the embodiment described above is not limited to the one used for the AlInGaP growth. For example, it may include an apparatus used for a nitride semiconductor crystal growth and makes it possible to grow the semiconductor layer having the homogeneous crystal composition and thickness.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

Note that, in this specification, “nitride semiconductor” includes BₓIn_{y}Al_{z}Ga_{(1-x-y-z)}N (where 0≦x=1, 0≦y≦5.1, 0≦z≦1, and 0≦x+y+z≦1) group III-V compound semiconductors, and furthermore includes mixed crystals including phosphorus (P) and/or arsenic (As) in addition to nitrogen (N) as group V elements. The “nitride semiconductor” includes a semiconductor further including various elements added for controlling various physical properties such as a conductivity type and a semiconductor further including various elements added unintentionally.

What is claimed is:

1. A semiconductor growth apparatus providing a semiconductor layer on a substrate, the apparatus comprising:
a susceptor including a first major surface, a second major surface and a substrate holder provided in the first major surface;
a heater element heating the susceptor from the second major surface side;
a gas feed unit feeding source gases of the semiconductor layer flowing along the first major surface; and
an auxiliary susceptor disposed on a portion adjacent to the substrate holder on an upstream side in the source gas flow in the first major surface.

2. The apparatus according to claim 1, wherein a surface temperature of the auxiliary susceptor is lower than a surface temperature of the susceptor, while the heater element heats the susceptor.

3. The apparatus according to claim 1, wherein a first depression holding the substrate is provided in the first major surface as the substrate holder.

4. The apparatus according to claim 1, wherein a second depression holding the auxiliary susceptor is provided in the first major surface.

5. The apparatus according to claim 4, wherein the susceptor holds the auxiliary susceptor in the second depression with a gap between the auxiliary susceptor and the bottom face of the second depression.

6. The apparatus according to claim 4, wherein the second depression is provided with a step along a side wall and the step supports a peripheral portion of the auxiliary susceptor.

7. The apparatus according to claim 4, wherein a step height between a surface of the susceptor around the second depression and a surface of the auxiliary susceptor held in the second depression is lower than a height inducing turbulent flow of the source gases.

8. The apparatus according to claim 1, wherein the gas feed unit includes a plate opposed to the first major surface for feeding the source gases.

9. The apparatus according to claim 8, wherein the source gases flow from a center to a peripheral side in the first major surface.

10. The apparatus according to claim 1, wherein the susceptor is rotated in a plane opposed to the gas feed unit.

11. The apparatus according to claim 1, wherein the auxiliary susceptor is disposed in a peripheral portion in the first major surface.

12. The apparatus according to claim 1, wherein the auxiliary susceptor is disposed in a center portion and a peripheral portion in the first major surface.

13. The apparatus according to claim 1, wherein one of the source gases includes trimethylindium (TMI).

14. The apparatus according to claim 13, wherein the source gases further include trimethylaluminum (TMA), trimethylgallium (TMG) and phosphine (PH₃); and the semiconductor layer including AlInGaP is provided on the substrate.

15. The apparatus according to claim 1, wherein the semiconductor layer including nitride semiconductor is provided on the substrate.

16. The apparatus according to claim 1, wherein the susceptor contains silicon or carbon.

17. The apparatus according to claim 1, wherein the auxiliary susceptor contains one of silicon carbide, boron nitride and carbon.

18. The apparatus according to claim 1, wherein the auxiliary susceptor includes the same material with the substrate or a material having a similar thermometric conductivity with the substrate.

19. The apparatus according to claim 1, wherein the auxiliary susceptor contains GaAs.

20. The apparatus according to claim 4, wherein the auxiliary susceptor is in contact with a bottom face of the second depression; and the auxiliary susceptor has a smaller thermometric conductivity than the susceptor.
